(19) United States
(12) Patent Application Publication
(10) Pub. No.: US 2024/0020744 A1
(43) Pub. Date: Jan. 18, 2024

(54) NON-TRANSITORY COMPUTER-READABLE MEDIUM STORING INFORMATION PROCESSING PROGRAM

(71) Applicant: TOYOTA JIDOSHA KABUSHIKI KAISHA, Toyota-shi Aichi-ken (JP)

(72) Inventor: Kyohei MASUI, Edogawa-ku Tokyo-to (JP)

(73) Assignee: TOYOTA JIDOSHA KABUSHIKI KAISHA, Toyota-shi Aichi-ken (JP)

(21) Appl. No.: 18/219,170

(22) Filed: Jul. 7, 2023

(30) Foreign Application Priority Data
Jul. 15, 2022 (JP) 2022-114332

(51) Int. Cl. G06Q 30/0601; G06Q 10/02

(52) U.S. Cl. CPC G06Q 30/0621; G06Q 30/0643; G06Q 30/0631; G06Q 10/02

(57) ABSTRACT

A computer-readable medium storing an information processing program executable by a computer to perform a process, the process including: allowing a user who wants to use a vehicle to select a layout of a component to be disposed in a cabin space in the vehicle, other than a seat for driving; and displaying on a display unit the layout of the component in the cabin space that has been decided upon by the user.

### CROSS-REFERENCE TO RELATED APPLICATION

This application claims priority under 35 USC 119 from Japanese Patent Application No. 2022-114332, filed on Jul. 15, 2022, the disclosure of which is incorporated by reference herein.

### BACKGROUND

### Technical Field

The present disclosure relates to a non-transitory computer-readable medium storing an information processing program.

### Related Art

There are technologies that allow information relating to a vehicle to be displayed on a user terminal. For example, Japanese Patent Application Laid-open (JP-A) No. 2022-075349, discloses a technology where power delivery capacity information representing the power delivery capacity of a storage battery mounted in a vehicle is displayed on a user terminal.

In this connection, when customizing a vehicle, users want not just to one-sidedly acquire information relating to the vehicle but also have their requirements for the vehicle be reflected in the vehicle. Specifically, when creating an interior design for a vehicle, users want to be satisfied with the interior design in advance before using the vehicle, and thus there is room for improvement.

### SUMMARY

The present disclosure provides a non-transitory computer-readable medium storing an information processing program that may allow a user to create in advance, an interior design for a vehicle the user wants to use.

A first aspect of the disclosure is a non-transitory computer-readable medium storing an information processing program executable by a computer to perform a process, the process including: allowing a user who wants to use a vehicle to select a layout of a component to be disposed in a cabin space in the vehicle, other than a seat for driving; and displaying on a display unit the layout of the component in the cabin space that has been decided upon by the user.

The information processing program according to the first aspect causes a computer to execute a process to allow a user who wants to use a vehicle to select a layout of a component disposed in a cabin space in the vehicle other than a seat for driving. The information processing program also causes the computer to execute a process to display on a display unit the layout of the component in the cabin space that has been decided upon by the user. Because of this, the information processing program may allow the user to create in advance an interior design for a vehicle the user wants to use.

In a second aspect of the disclosure, in the first aspect, the process may further include: receiving a change made by the user to at least one of the layout, dimensions, or color of the component disposed in the cabin space.

The information processing program according to the second aspect causes the computer to execute a process to receive a change made by the user to at least one of the layout, dimensions, and color of the component disposed in the cabin space. Because of this, the information processing program may allow the user to adjust at least one of the layout, dimensions, and color of the component disposed in the cabin space.

In a third aspect of the disclosure, in the first or second aspect, the process may further include: acquiring user information relating to the user, and recommending a layout of the component for the user, based on the user information that is acquired.

The information processing program according to the third aspect causes the computer to execute a process to acquire user information relating to the user. The information processing program also causes the computer to execute a process to recommend, based on the acquired user information, a layout of the component for the user. Because of this, the information processing program can allow the user to create in advance, using a layout of the component according to the characteristics of the user, an interior design for a vehicle the user wants to use.

In a fourth aspect of the disclosure, in any one of the first to third aspects, the process may further include: displaying on the display unit vehicle information relating to the driving performance of the vehicle, in a case in which the component that has been decided by the user is disposed in the cabin space.

The information processing program according to the fourth aspect causes the computer to execute a process to display on the display unit vehicle information relating to the driving performance of the vehicle in a case in which the component that has been decided upon by the user is disposed in the cabin space. Because of this, the information processing program may allow the user to grasp in advance vehicle information in a case in which the component is disposed in the vehicle.

In a fifth aspect of the disclosure, in any one of the first to fourth aspects, the process may further include: receiving a reservation to use the vehicle in which the component that has been decided by the user is disposed in the cabin space.

The information processing program according to the fifth aspect causes the computer to execute a process to receive a reservation to use the vehicle in which the component that has been decided upon by the user is disposed in the cabin space. Because of this, the information processing program may allow the user to use the vehicle whose interior design the user has created in advance.

According to the above aspects, the non-transitory computer-readable medium storing the information processing program according to the present disclosure may allow a user to create in advance an interior design for a vehicle the user wants to use.

### BRIEF DESCRIPTION OF THE DRAWINGS

An exemplary embodiment will be described in detail based on the following figures, wherein:

FIG. 1 is a diagram illustrating the schematic configuration of an information processing system;

FIG. 2 is a block diagram illustrating hardware configurations of a user terminal;

FIG. 3 is a flowchart illustrating a flow of a design process performed by the user terminal;

FIG. 4 is a first display example displayed on a display unit of the user terminal;

FIG. 5 is a second display example displayed on the display unit of the user terminal; and

FIG. 6 is a third display example displayed on the display unit of the user terminal.

### DETAILED DESCRIPTION

An information processing system 10 according to the embodiment will now be described below. The information processing system 10 according to the embodiment is a system that may allow a user to create in advance an interior design for a vehicle the user wants to use.

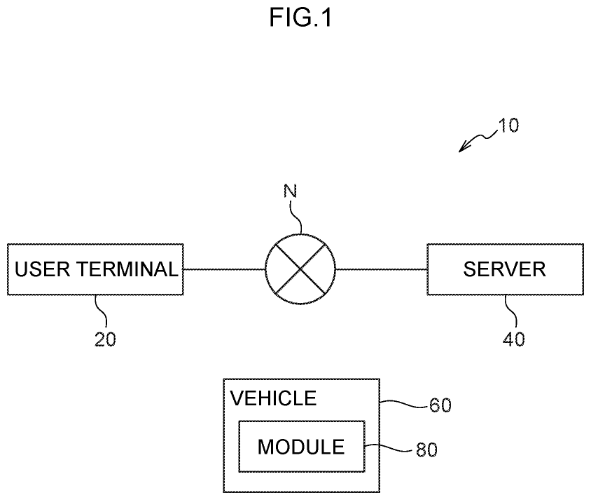

FIG. 1 is a diagram illustrating the schematic configuration of the information processing system 10. As illustrated in FIG. 1, the information processing system 10 includes a user terminal 20, a server 40, and a vehicle 60. The user terminal 20 and the server 40 are connected via a network N so as to be communicable with each other.

The user terminal 20 is a smartphone owned by the user who wants to use the vehicle 60. In the user terminal 20 is installed an application for creating an interior design for the vehicle 60 (hereinafter called “the design app”).

The server 40 is a server computer owned by a predetermined business operator. The vehicle 60 is a two-seater car not provided with rear seats. The vehicle 60 is able to have a module 80 such as a sofa and a table disposed in the cabin space other than a seat for driving, specifically, in back of a driver's seat and a front passenger seat, so that the user can create a cabin space that is to his/her liking.

The module 80 is standardized in conformity to the vehicle 60 and is provided with anchor portions (not illustrated in the drawings) that can be anchored to anchor receiving portions provided in the cabin space of the vehicle 60. By anchoring the anchor portions of the module 80 to the anchor receiving portions of the vehicle 60, the module 80 can be disposed in the vehicle 60. Note that the module 80 is detachably anchored to the vehicle 60. The module 80 is an example of a “component.”

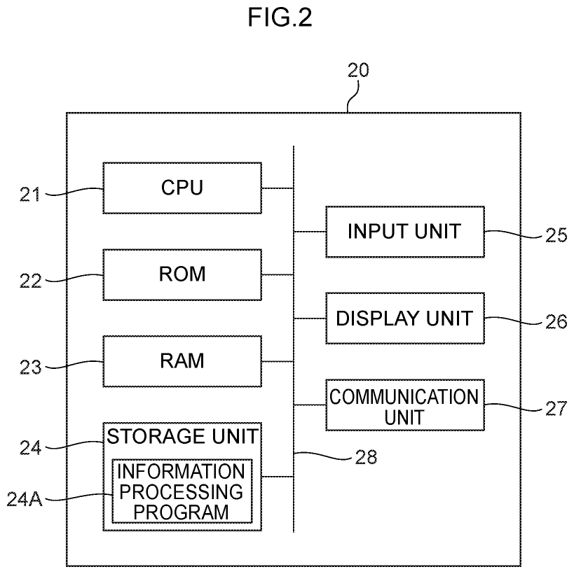

Next, hardware configurations of the user terminal 20 will be described. FIG. 2 is a block diagram illustrating the hardware configurations of the user terminal 20.

As illustrated in FIG. 2, the user terminal 20 includes a central processing unit (CPU) 21, a read-only memory (ROM) 22, a random-access memory (RAM) 23, a storage unit 24, an input unit 25, a display unit 26, and a communication unit 27. These configurations are communicably connected to each other via a bus 28.

The CPU 21 is a central processing unit, executes various types of programs, and controls each section of the user terminal 20. That is, the CPU 21 reads programs from the ROM 22 or the storage unit 24 and executes the programs using the RAM 23 as a workspace. The CPU 21 controls each of the above configurations and performs various types of arithmetic processing in accordance with the programs recorded in the ROM 22 or the storage unit 24.

The ROM 22 stores various types of programs and various types of data. The RAM 23 temporarily stores programs or data as a workspace.

The storage unit 24 is configured by a storage device such as an embedded multimedia card (eMMC) or universal flash storage (UFS) and stores various types of programs and various types of data. In the storage unit 24 is stored an information processing program 24A executed by the CPU 21 to perform a design process described later.

The input unit 25 includes various types of buttons, a microphone, and a camera, and is used to perform various types of input.

The display unit 26 is, for example, a liquid crystal display and displays various types of information. The display unit 26 employs a touch panel system and also functions as the input unit 25. The display unit 26 is an example of a “display unit.”

The communication unit 27 is a wireless communication module for communicating with the server 40. The wireless communication module uses a communication protocol such as, for example, 5G, LTE, or Wi-Fi (registered trademark). The communication unit 27 is connected to the network W.

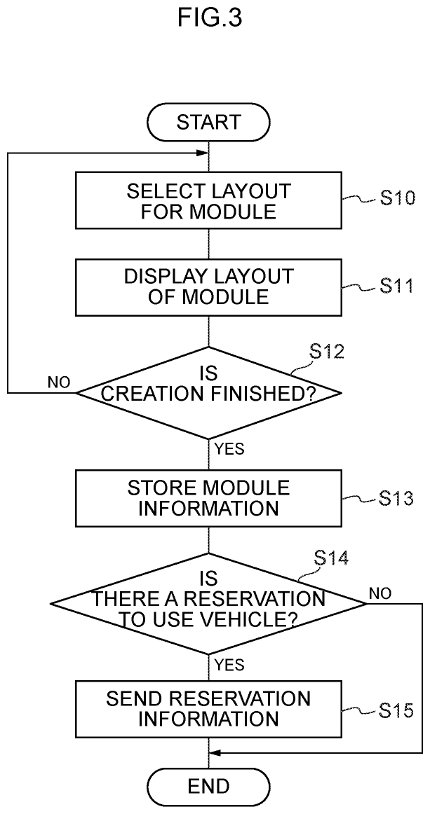

FIG. 3 is a flowchart illustrating the flow of a design process by which the user creates in advance, using the user terminal 20, an interior design for the vehicle 60 the user wants to use. The design process is performed as a result of the CPU 21 reading the information processing program 24A from the storage unit 24, loading the program to the RAM 23, and executing the program.

In step S10 illustrated in FIG. 3, the CPU 21 receives a selection, made by the user, of a layout of the module 80 disposed in the cabin space of the vehicle 60. Then, the CPU 21 proceeds to step S11.

In step S11, the CPU 21 displays on the display unit 26 the layout of the module 80 in the cabin space that was selected in step S10. Then, the CPU 21 proceeds to step S12.

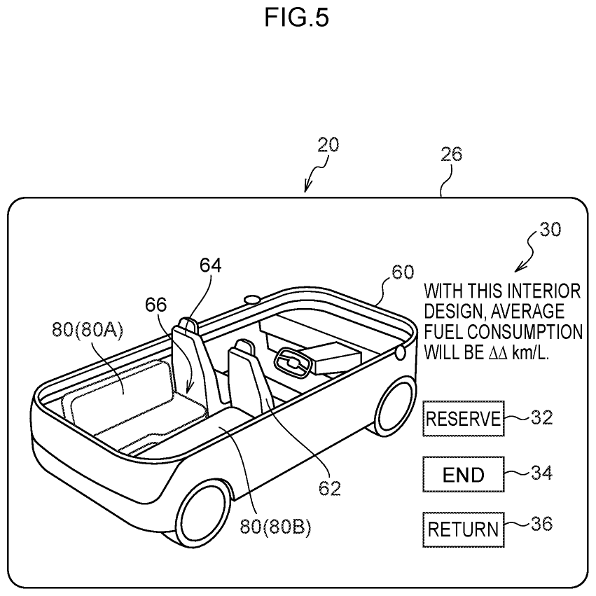

In step S12, the CPU 21 determines whether or not the creation of the interior design for the vehicle 60 is finished. In a case in which the CPU 21 determines that the creation is finished (step S12: YES), the process proceeds to step S13. In a case in which the CPU 21 determines that the creation of the interior design for the vehicle 60 is not finished (step S12: NO), the process returns to step S10. As an example, the CPU 21 determines that the creation of the interior design for the vehicle 60 is finished in a case in which a reserve button 32 or an end button 34 has been operated on a confirmation screen described later (see FIG. 5).

In step S13, the CPU 21 stores in the storage unit 24 module information relating to the layout of the module 80 disposed in the cabin space of the vehicle 60 that has been decided upon by the user. Then, the CPU 21 proceeds to step S14. The module information includes, as an example, the type, weight, layout, dimensions, and color of the module 80. Note that the CPU 21 links the module information stored in the storage unit 24 to identification information for identifying the user and regularly sends the information to the server 40.

In step S14, the CPU 21 determines whether or not the CPU 21 has received a reservation to use the vehicle 60 in which the module 80 is disposed in the cabin space. In a case in which the CPU 21 determines that the CPU 21 has received a reservation to use the vehicle 60 (step S14: YES), the process proceeds to step S15. In a case in which the CPU 21 determines that the CPU 21 has not received a reservation to use the vehicle 60 (step S14: NO), the process ends the design process. As an example, the CPU 21 determines that the CPU 21 has received a reservation to use the vehicle 60 in a case in which the reserve button 32 has been operated on the confirmation screen (see FIG. 5). Note that the reservation to use the vehicle 60 includes a reservation to test drive the vehicle 60 before purchasing the vehicle 60 and a reservation for temporarily using the vehicle 60 through a car-sharing or rental car service, for example.

In step S15, the CPU 21 sends to the server 40 reservation information regarding the reservation to use the vehicle 60 including the module information stored in the storage unit 24. Then, the CPU 21 ends the design process.

Next, display examples of the design app displayed on the display unit 26 as a result of the design process illustrated in FIG. 3 being performed by the user terminal 20 will be described.

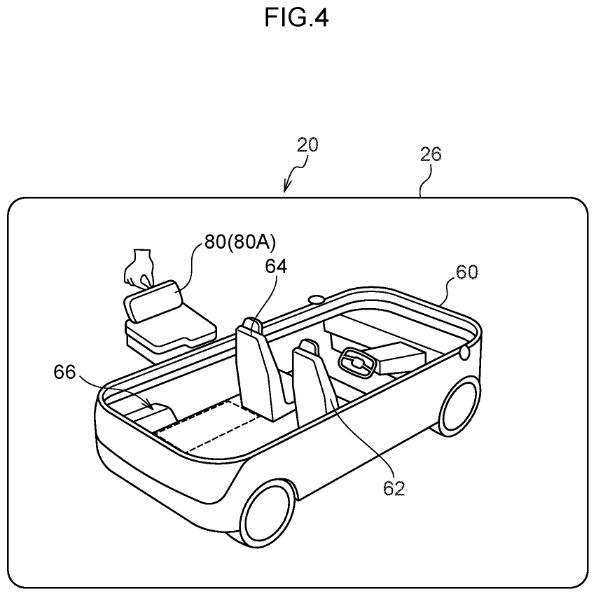

FIG. 4 is a first display example displayed on the display unit 26 of the user terminal 20. Specifically, FIG. 4 illustrates an arrangement screen in which a sofa 80A is selected as the module 80 disposed in a cabin space 66 in back of a driver's seat 62 and a front passenger seat 64 of the vehicle 60 and in which the sofa 80A is disposed in the cabin space 66.

The module 80 can be disposed in an arbitrary position in the cabin space 66. As an example, in the arrangement screen illustrated in FIG. 4, the layout position of the sofa 80A is indicated by the dashed line. Furthermore, the user terminal 20 receives on the arrangement screen changes made by the user to the layout, dimensions, and color of the module 80 disposed in the cabin space 66. As an example, in the arrangement screen illustrated in FIG. 4, the layout of the sofa 80A disposed in the cabin space 66 can be changed, the dimensions of the sofa 80A can be increased or decreased, and the color of the sofa 80A can be changed based on a predetermined operation with respect to the user terminal 20.

FIG. 5 is a second display example displayed on the display unit 26 of the user terminal 20. Specifically, FIG. 5 illustrates a confirmation screen, which is a screen to which the display unit 26 transitions from the arrangement screen and with which the user can confirm the layout of the module 80 in the cabin space 66 that has been decided upon by the user.

On the confirmation screen illustrated in FIG. 5, the vehicle 60, message information 30, a reserve button 32, an end button 34, and a return button 36 are displayed.

In the vehicle 60 illustrated in FIG. 5, the sofa 80A and a table 80B are disposed as the module 80 in the cabin space 66.

The message information 30 illustrates various types of messages to the user. As an example, in FIG. 5, the message “With this interior design, the average fuel consumption will be ΔΔ km/L” is displayed as the message information 30. In this way, the message information 30 illustrated in FIG. 5 illustrates vehicle information relating to the driving performance of the vehicle 60 in a case in which the module 80 that has been decided upon by the user is disposed in the cabin space 66.

Here, the storage unit 24 stores fuel consumption information representing the average fuel consumption of the vehicle 60 in a state in which the module 80 is not disposed therein. Additionally, the CPU 21 of the user terminal 20 decides the average fuel consumption displayed in the message information 30 based on the fuel consumption information and the module information stored in the storage unit 24.

The reserve button 32 is a button for making a reservation to use the vehicle 60 in which the module 80 is disposed in the cabin space 66. In a case in which the reserve button 32 illustrated in FIG. 5 is operated, the CPU 21 stores in the storage unit 24 module information corresponding to the vehicle 60 displayed on the confirmation screen. Then, the CPU 21 sends to the server 40 reservation information including this module information.

The end button 34 is a button for ending the design app without making a reservation to use the vehicle 60. In a case in which the end button 34 is operated, the CPU 21 stores in the storage unit 24 module information corresponding to the vehicle 60 displayed on the confirmation screen and thereafter transitions the screen of the display unit 26 to predetermined content.

The return button 36 is a button for transitioning the screen of the display unit 26 to the arrangement screen. In a case in which the return button 36 is operated, the CPU 21 transitions the screen of the display unit 26 to the arrangement screen.

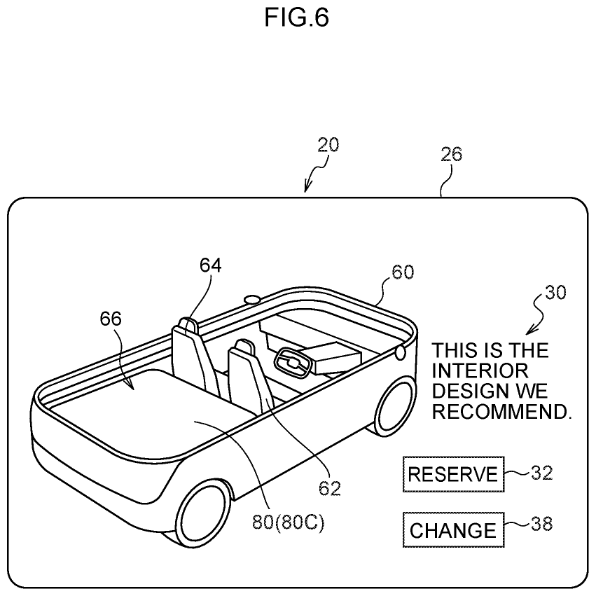

FIG. 6 is a third display example displayed on the display unit 26 of the user terminal 20. Specifically, FIG. 6 illustrates a recommendation screen in which a layout of the module 80 is recommended to the user based on user information relating to the user. As an example, the recommendation screen is displayed instead of the arrangement screen based on a predetermined operation with respect to the user terminal 20 on a predetermined screen.

Here, the user information includes, as an example, the age, sex, interests, occupation, and family makeup of the user. User information that has been input by the user is also stored in the storage unit 24.

The CPU 21 acquires the user information from the storage unit 24 in a case in which a predetermined operation has been performed with respect to the user terminal 20 on a predetermined screen. The CPU 21 sends the acquired user information to the server 40. The server 40 identifies another user, similar to the user, based on the user information, and sends module information of the identified other user to the user terminal 20. Then, the CPU 21 displays on the display unit 26 a layout of the module 80 corresponding to the module information of the other user.

Here, on the recommendation screen illustrated in FIG. 6, the vehicle 60, the message information 30, the reserve button 32, and a change button 38 are displayed.

In the vehicle 60 illustrated in FIG. 6, a simple bed 80C is disposed as the module 80 in the cabin space 66.

As an example, in FIG. 6, the message “This is the interior design we recommend” is displayed as the message information 30. In this way, the message information 30 illustrated in FIG. 6 recommends a layout for a specific module 80 for the user.

In a case in which the reserve button 32 illustrated in FIG. 6 is operated, the CPU 21 stores in the storage unit 24 module information corresponding to the vehicle 60 displayed on the recommendation screen. Then, the CPU 21 sends to the server 40 reservation information including the module information.

The change button 38 is a button for changing the interior design for the vehicle 60 while maintaining the layout of the module 80 disposed in the cabin space 66 on the recommendation screen. In a case in which the change button 38 is operated, the CPU 21 transitions the screen of the display unit 26 to the arrangement screen.

In the above embodiment, the user terminal 20 receives changes made by the user on the arrangement screen to the layout, dimensions, and color of the module 80 disposed in the cabin space 66. However, the present disclosure not limited thereto, and the user terminal 20 may receive a change made by the user on the arrangement screen to at least one of the layout, dimensions, and color of the module 80 disposed in the cabin space 66.

In the above embodiment, the average fuel consumption in a case in which the module 80 is disposed in the cabin space 66 was displayed as the vehicle information on the display unit 26, but the vehicle information is not limited thereto. For example, instead of or in addition, the CPU 21 may display, as the vehicle information on the display unit 26, acceleration performance and braking performance in a case in which the module 80 is disposed in the cabin space 66.

In the above embodiment, one pattern for the layout of the module 80 for the user based on the user information was displayed, but the number of patterns is not limited thereto, and more than one pattern for the layout of the module 80 may be recommended to the user. Furthermore, in the above embodiment, a layout for the module 80 for the user based on the user information was recommended, but the CPU 21 is not limited thereto and may display on the display unit 26 plural samples of layouts of the module 80 prepared beforehand.

In the above embodiment, the information processing system 10 may be configured so that users can communicate with each other through the design app. Because of this, for example, one user can create an interior design for the vehicle 60 while consulting another user.

In the above embodiment, the information processing system 10 may be configured so that the user can browse, through the design app, interior designs for the vehicle 60 that other users have created.

In the above embodiment, the vehicle 60 having an interior design the user has created may be displayed on the display unit 26 using augmented reality (AR) technology through the design app.

In the above embodiment, the information processing system 10 may be configured to allow the user to make, through the design app, a reservation to have a worker install the module 80 and a reservation to store the module 80 that is no longer needed.

In the above embodiment, the information processing system 10 may be configured to allow the user to purchase, through the design app, the vehicle 60 whose interior design the user has created.

In the above embodiment, the module 80 was able to be disposed in the cabin space in back of the driver's seat and the front passenger seat of the vehicle 60. However, the module 80 is not limited thereto and, in a vehicle 60 not provided with a front passenger seat, may also be able to be disposed in the cabin space other than where the driver's seat is.

It will be noted that the design process that the CPU 21 executed by reading software (a program) in the above embodiment may also be executed by various types of processors other than a CPU. Examples of processors in this case include programmable logic devices (PLDs) whose circuit configuration can be changed after manufacture, such as field-programmable gate arrays (FPGAs), and dedicated electrical circuits that are processors having a circuit configuration dedicatedly designed for executing specific processes, such as application-specific integrated circuits (ASICs). Furthermore, the design process may be executed by one of these various types of processors or may be executed by a combination of two or more processors of the same type or different types (e.g., plural FPGAs, and a combination of a CPU and an FPGA, etc.). Furthermore, the hardware structures of these various types of processors are more specifically electrical circuits in which circuit elements such as semiconductor elements are combined.

Furthermore, in the above embodiment, an aspect was described where the information processing program 24A is stored (installed) beforehand in the storage unit 24, but the information processing program 24A is not limited thereto. The information processing program 24A may also be recorded in a recording medium such as a compact disc read-only memory (CD-ROM), a digital versatile disc read-only memory (DVD-ROM), and a universal serial bus (USB) memory. Furthermore, the information processing program 24A may be downloaded via the network N from an external device.

What is claimed is:

1. A non-transitory computer-readable medium storing an information processing program executable by a computer to perform a process, the process comprising:
allowing a user who wants to use a vehicle to select a layout of a component to be disposed in a cabin space in the vehicle, other than a seat for driving; and
displaying on a display unit the layout of the component in the cabin space that has been decided upon by the user.

2. The non-transitory computer-readable medium of claim 1, the process further comprising: receiving a change made by the user to at least one of the layout, dimensions, or color of the component disposed in the cabin space.

3. The non-transitory computer-readable medium of claim 1, the process further comprising: acquiring user information relating to the user, and recommending a layout of the component for the user, based on the user information that is acquired.

4. The non-transitory computer-readable medium of claim 1, the process further comprising: displaying on the display unit vehicle information relating to a driving performance of the vehicle, in a case in which the component that has been decided by the user is disposed in the cabin space.

5. The non-transitory computer-readable medium of claim 1, the process further comprising: receiving a reservation to use the vehicle in which the component that has been decided by the user is disposed in the cabin space.
